(19) United States
(12) Patent Application Publication
(10) Pub. No.: US 2010/0099250 A1
(43) Pub. Date: Apr. 22, 2010

(54) Methods of Forming Integrated Circuit Contact Pads Using Electroless Plating of Diffusion Barrier Layers

(75) Inventors: Woo Jin Jang, Fishkill, NY (US); Sung Dong Cho, Fishkill, NY (US); Bum Ki Moon, LaGrangeville, NY (US)

Correspondence Address: MYERS BIGEL SIBLEY & SAJOVEC, PO BOX 37428, RALEIGH, NC, 27627, US

(73) Assignees: Samsung Electronics Co., Ltd.; Infineon Technologies North America Corp.

(21) Appl. No.: 12/255,329

(22) Filed: Oct. 21, 2008

(51) Int. Cl. H01L 21/44

(52) U.S. Cl. 438/614; 257/E21.476

(57) ABSTRACT

Methods of forming a contact pad include forming a copper pattern on a semiconductor substrate and forming a passivation layer on the copper pattern. The passivation layer is defined to have an opening therein that exposes at least a portion of an upper surface of the copper pattern. A diffusion barrier layer is formed in the opening by electroless plating the diffusion barrier layer onto the exposed portion of the upper surface of the copper pattern. This diffusion barrier layer operates as a barrier to copper out-diffusion from the copper pattern. These methods further include conformally depositing an underbump metallization layer onto at least a sidewall of the opening in the passivation layer and onto an upper surface of the diffusion barrier layer. A step is then performed to plate a contact bump (e.g., solder bump) onto a portion of the underbump metallization layer extending opposite the diffusion barrier layer.

### FIELD OF THE INVENTION

The present invention relates to methods of fabricating integrated circuit devices and, more particularly, to methods of fabricating integrated circuit devices having contact pads thereon.

### BACKGROUND OF THE INVENTION

Conventional methods of forming contact pads on integrated circuit chips typically include forming an electrically conductive pad on an electrically insulating passivation layer that covers an integrated circuit substrate. This electrically conductive pad may be electrically connected to an uppermost level of metallization, which interconnects electrical devices within an underlying semiconductor region (e.g., a semiconductor substrate). Some of these conventional methods are illustrated by FIGS. 1A-1E. In particular, FIG. 1A illustrates an interlayer dielectric layer 10 formed as an upper insulating layer on an underlying integrated circuit substrate (not shown) having active devices therein. Conventional damascene techniques may also be used to form an upper level wiring pattern 14 (e.g., copper pattern) in the interlayer dielectric layer 10. A diffusion barrier layer 12 may also be formed that lines a patterned recess within the interlayer dielectric layer 10. This diffusion barrier layer 12 may be a metal layer that is used to inhibit out-diffusion of metal atoms (e.g., Cu atoms) from the wiring pattern 14 to the surrounding interlayer dielectric layer 10. An electrically insulating capping layer 16 (e.g., a SiCN layer) is formed on the interlayer dielectric layer 10 and an oxide passivation layer 18 is formed on the capping layer 16.

Referring now to FIG. 1B, a photoresist layer 20 is deposited on the passivation layer 18 and then patterned to define an opening therein. The patterned photoresist layer 20 is used as an etching mask during a step to selectively etch through the passivation layer and capping layer 16 and define a contact hole that exposes an upper surface of the wiring pattern 14, as illustrated by FIG. 1C. Thereafter, as illustrated by FIGS. 1D-1E, an aluminum layer 22 is conformally deposited on the passivation layer 18 and then selectively etched to define an aluminum pad 22, using a patterned photoresist layer 24 as an etching mask. An electrically insulating passivation layer 26 is then formed on the aluminum pad 22. An opening is formed in this passivation layer 26 in order to expose a portion of an upper surface of the aluminum pad 22. Conventional techniques may then be used to define a solder bump in the opening, which may be used for flip-chip packaging, or the opening may be used to enable direct wire bonding to the aluminum pad 22.

Conventional methods of forming contact pads that are compatible with flip-chip bonding are also illustrated by FIGS. 2A-2G. In particular, FIG. 2A illustrates a plurality of patterned copper layers 42a and 42b, which may be formed in an interlayer insulating layer 40 using conventional damascene fabrication techniques. A stack of electrically insulating layers, which include a capping layer 44, a silicon dioxide layer 46 and a silicon nitride layer 48, is formed on the interlayer insulating layer 40. Referring now to FIGS. 2B-2D, this stack of electrically insulating layers is then photolithographically patterned to define a contact opening 49 therein, which exposes an upper surface of a patterned copper layer 42a. An electrically conductive layer 50 (e.g., TiN metal layer) is conformally deposited into the contact opening 49. A chemical mechanical polishing (CMP) step is performed to planarize the electrically conductive layer 50 and thereby define a contact liner 50a.

Thereafter, as illustrated by FIGS. 2E-2F, an underbump metallization (UBM) layer 52 is conformally deposited onto the silicon nitride layer 48 and onto the contact liner 50a. As illustrated by FIG. 2F, a patterned photoresist layer 54 is then formed on the UBM layer 52. The patterned photoresist layer 54 exposes a portion of the UBM layer 52 extending into the contact opening 49. This UBM layer 52 may be used to electroplate a solder layer 56 into the contact opening 49. Referring now to FIG. 2G, the photoresist layer 54 is then removed and followed by the step of etching back the UBM layer 52 using the solder layer 56 as an etching mask. A solder reflow step is then performed to convert the solder layer 56 into a solder bump 56a.

### SUMMARY OF THE INVENTION

Methods of forming a contact pad according to embodiments of the present invention include forming a copper pattern on a semiconductor substrate and forming a passivation layer on the copper pattern. The passivation layer is defined to have an opening therein that exposes at least a portion of an upper surface of the copper pattern. A diffusion barrier layer is formed in the opening by electroless plating the diffusion barrier layer onto the exposed portion of the upper surface of the copper pattern. This diffusion barrier layer operates as a barrier to copper out-diffusion from the copper pattern. These methods further include conformally depositing an underbump metallization layer onto at least a sidewall of the opening in the passivation layer and onto an upper surface of the diffusion barrier layer. A step is then performed to plate a contact bump (e.g., solder bump) onto a portion of the underbump metallization layer extending opposite the diffusion barrier layer. According to some of these embodiments of the invention, the step of plating a contact bump is preceded by depositing a photoresist layer on the underbump metallization layer and patterning the photoresist layer to define an opening therein that exposes a portion of the underbump metallization layer extending opposite the diffusion barrier layer. The step of plating a contact bump may also be followed by a step of selectively etching back the underbump metallization layer using the solder bump as an etching mask.

Additional embodiments of the invention include forming a contact pad by forming a copper pattern on a semiconductor substrate and then forming a passivation layer having an opening therein, which exposes at least a portion of an upper surface of the copper pattern. An electroless plating step is then performed to form a diffusion barrier layer containing cobalt directly onto the exposed portion of the upper surface of the copper pattern. According to some of these embodiments of the invention, the diffusion barrier layer may be a CoWP, CoWPB or CoWB layer, for example.

These methods may also include the steps of depositing an underbump metallization layer onto the passivation layer and onto an upper surface of the diffusion barrier layer, and then plating a solder bump onto a portion of the underbump metallization layer extending opposite the diffusion barrier layer. The underbump metallization layer is then selectively etched back to expose the passivation layer. During this etching step, the solder bump is used as an etching mask. The underbump metallization layer may include a composite of a titanium-based diffusion barrier layer and a gold and/or platinum metal layer on the titanium-based diffusion barrier layer. The passivation layer may also be formed as a composite of a SiCN capping layer, a silicon dioxide insulating layer on the SiCN capping layer, and a silicon nitride insulating layer on the silicon dioxide insulating layer.

Additional embodiments of the invention include forming a contact pad by forming a two-dimensional array of copper patterns in an interlayer insulating layer and then forming a multi-layered passivation layer having an opening therein that exposes the two-dimensional array of copper patterns. An electroless plating step is then performed to define an array of spaced-apart diffusion barrier layers containing cobalt, onto the two-dimensional array of copper patterns. An underbump metallization layer is then deposited directly onto the array of spaced-apart diffusion barrier layers and onto portions of the interlayer insulating layer extending between the two-dimensional array of copper patterns. A solder bump is then plated onto the underbump metallization layer.

### BRIEF DESCRIPTION OF THE DRAWINGS

FIGS. 1A-1E are cross-sectional views of intermediate structures that illustrate methods of forming contact pads according to the prior art.

FIGS. 2A-2G are cross-sectional views of intermediate structures that illustrate methods of forming contact pads according to the prior art.

FIGS. 3A-3F are cross-sectional views of intermediate structures that illustrate methods of forming contact pads according to embodiments of the present invention.

FIG. 4 is a cross-sectional view of an intermediate structure that illustrates methods of forming contact pads according to alternative embodiments of the present invention.

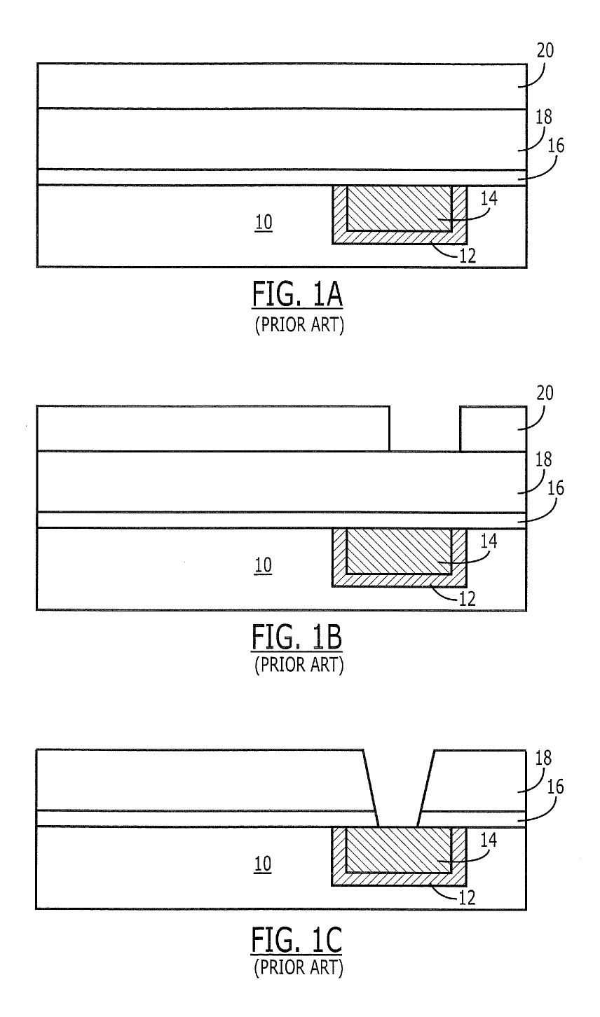

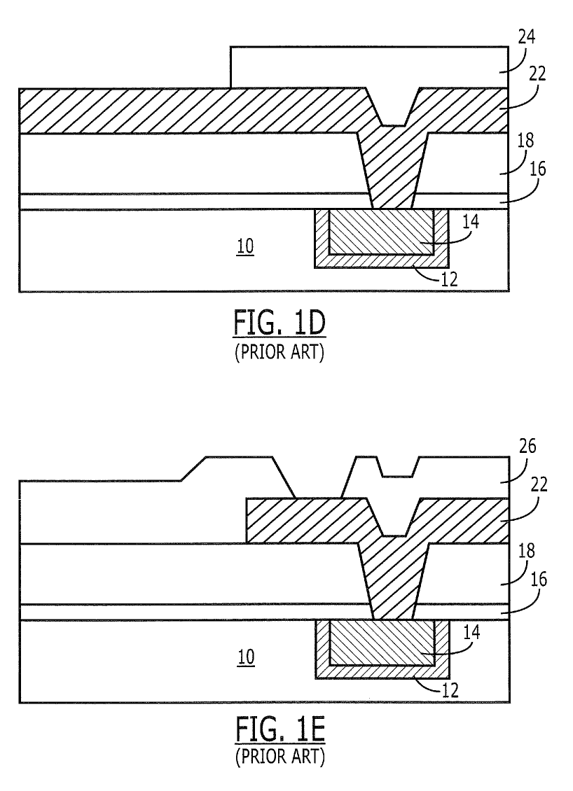

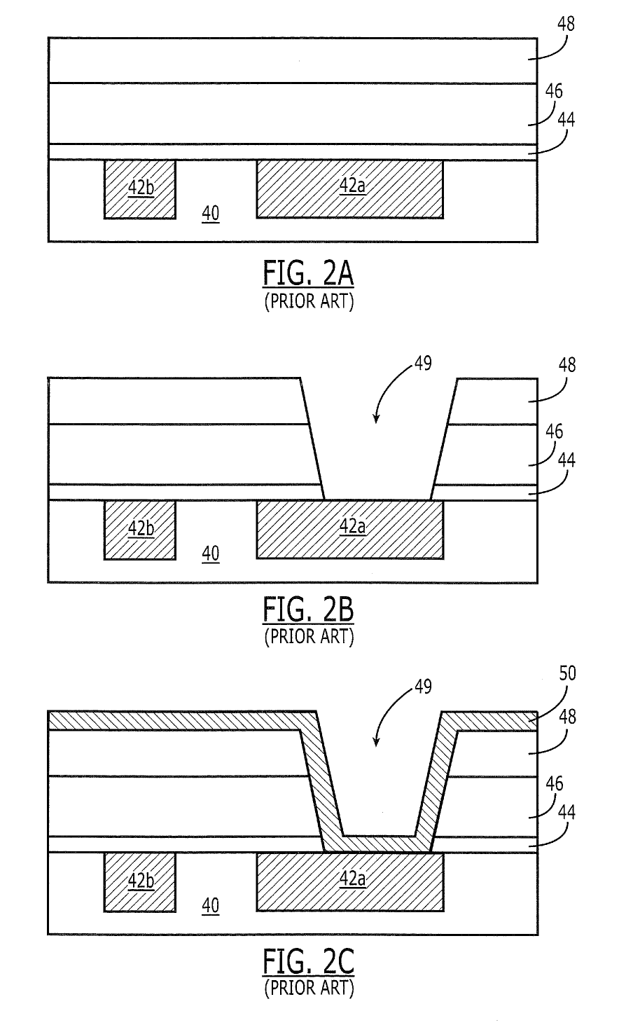

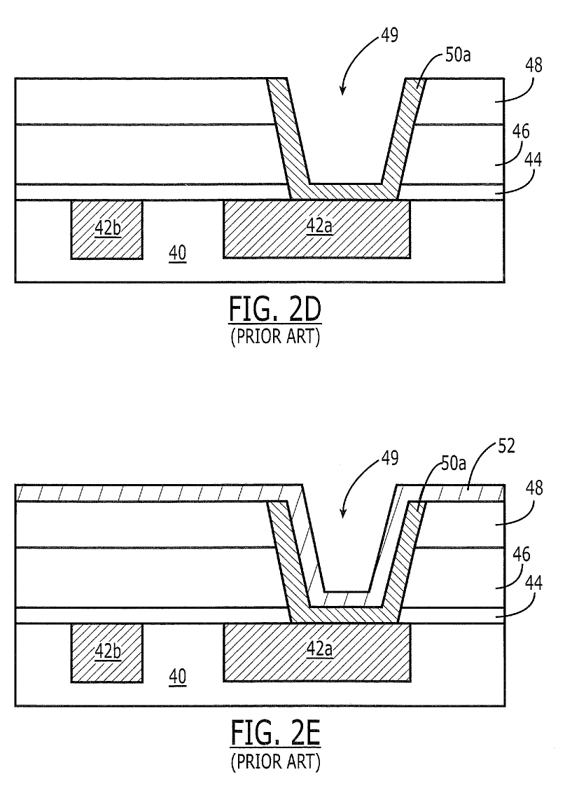

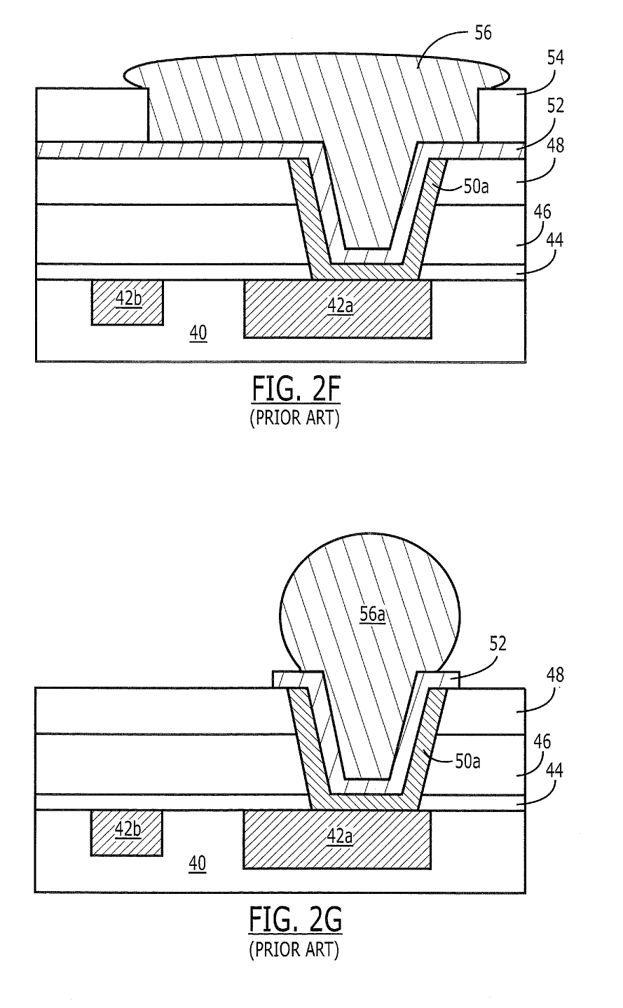

### DETAILED DESCRIPTION OF PREFERRED EMBODIMENTS

The present invention will now be described more fully hereinafter with reference to the accompanying drawings, in which preferred embodiments of the invention are shown. This invention may, however, be embodied in different forms and should not be construed as limited to the embodiments set forth herein. Rather, these embodiments are provided so that this disclosure will be thorough and complete, and will fully convey the scope of the invention to those skilled in the art. In the drawings, the thickness of layers and regions are exaggerated for clarity. It will also be understood that when a layer is referred to as being “on” another layer or substrate, it can be directly on the other layer or substrate, or intervening layers may also be present. Like numbers refer to like elements throughout.

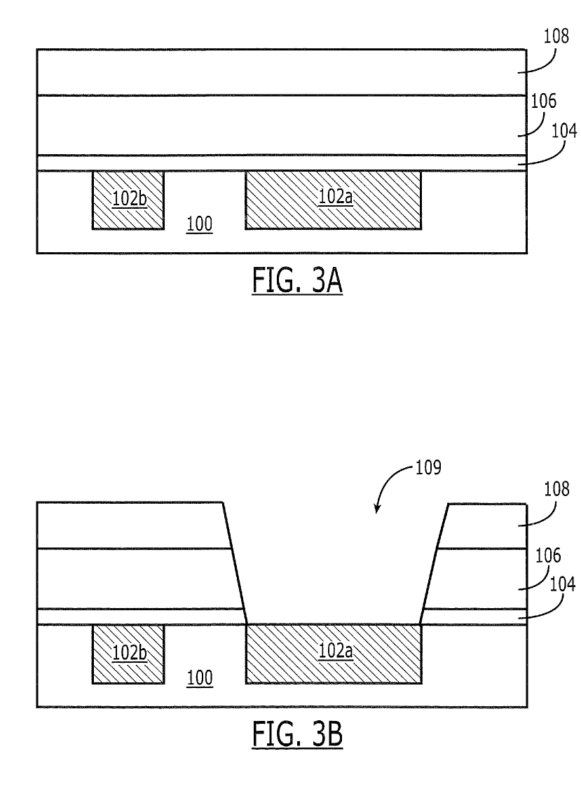

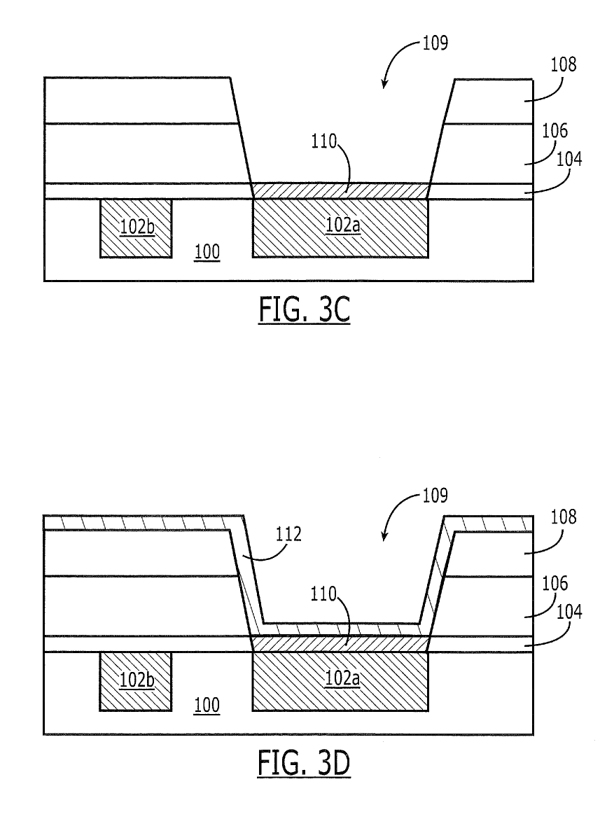

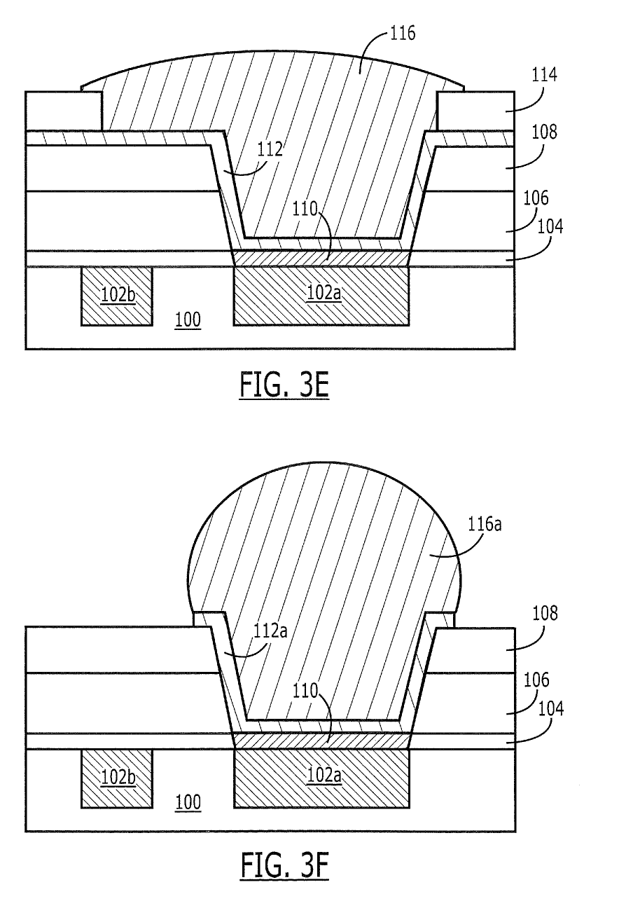

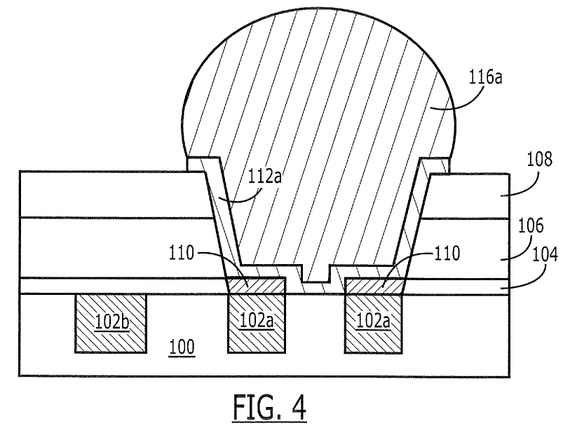

Referring now to FIGS. 3A-3F, methods of forming contact pads according to some embodiments of the present invention include forming a copper pattern on a semiconductor substrate and forming a passivation layer on the copper pattern. As illustrated by FIG. 3A, a plurality of patterned copper layers 102a and 102b may be formed in an interlayer dielectric layer 100 using damascene patterning techniques, for example. The interlayer dielectric layer 100 may be formed as an upper electrically insulating layer on a substrate (e.g., semiconductor substrate). A passivation layer is then formed on the interlayer dielectric layer 100. The passivation layer, which may have a thickness in a range from about 5,000 Å to about 20,000 Å, may be formed as a composite of multiple different electrically insulating materials. In particular, this passivation layer is illustrated as including an electrically insulating capping layer 104, which is formed directly on the interlayer dielectric layer 100. This capping layer 104 may be formed as a SiCN layer having a thickness in a range from about 500 Å to about 5,000 Å. The passivation layer is also illustrated as including a silicon dioxide insulating layer 106 on the capping layer 104 and a silicon nitride insulating layer 108 on the silicon dioxide insulating layer 106.

Referring now to FIGS. 3B-3C, a photolithographically defined etching step is then performed to define a contact opening 109 that extends through the passivation layer and exposes an upper surface of the patterned copper layer 102a. An electroless plating step is then performed to define a diffusion barrier layer 110 that is self-aligned to the contact opening 109. The diffusion barrier layer 110, which may inhibit out-diffusion of copper from the patterned copper layer 102a, may be a CoWP, CoWPB or CoWB layer, for example, and may have a thickness in a range from about 10 Å to about 5,000 Å. The diffusion barrier layer 110 may also support relatively high current densities by inhibiting electromigration from the patterned copper layer 102a.

Thereafter, as illustrated by FIG. 3D, an underbump metallization layer 112 is conformally deposited into the contact opening 109 and onto the diffusion barrier layer 110. This underbump metallization layer 112 may be formed as a gold (Au) layer having a thickness in a range from about 500 Å to about 2,000 Å. Alternatively, the underbump metallization layer 112 may include a composite of a nickel-based diffusion barrier layer and a gold and/or platinum metal layer on the titanium-based diffusion barrier layer. A photoresist layer is then formed on the underbump metallization layer 112 and patterned to define a patterned photoresist layer 114 that exposes the opening 109, as illustrated by FIG. 3E. A solder bump layer 116 is then plated into the opening 109. The patterned photoresist layer 114 is then removed and a reflow step is performed to define a final solder bump 116a on an underbump metallization layer 112a, as illustrated by FIG. 3F. The exposed underbump metallization layer 112 is then selectively etched back using the solder bump 116a as an etching mask. According to additional embodiments of the invention, the method embodiments illustrated by FIGS. 3A-3F may be used to define the solder bump 116a of FIG. 4, which is electrically connected to a plurality (e.g., two-dimensional array) of patterned copper layers 102a by a corresponding plurality of diffusion barrier layers 110 formed by electroless plating.

In the drawings and specification, there have been disclosed typical preferred embodiments of the invention and, although specific terms are employed, they are used in a generic and descriptive sense only and not for purposes of limitation, the scope of the invention being set forth in the following claims.

1. A method of forming a contact pad, comprising:
forming a copper pattern on a semiconductor substrate;
forming a passivation layer having an opening therein that exposes at least a portion of an upper surface of the copper pattern;
forming a diffusion barrier layer in the opening by electroless plating the diffusion barrier layer onto the exposed portion of the upper surface of the copper pattern;
conformally depositing an underbump metallization layer onto the passivation layer and onto an upper surface of the diffusion barrier layer;
depositing a photoresist layer on the underbump metallization layer;
patterning the photoresist layer to define an opening therein that exposes a first portion of the underbump metallization layer extending opposite the diffusion barrier layer;
plating an electrically conductive solder bump layer onto first and second portions of the underbump metallization layer within the opening in the patterned photoresist layer;
converting the electrically conductive solder bump layer into a solder bump by reflowing the electrically conductive solder bump layer onto the second portion of the underbump metallization layer to thereby expose the first portion of the underbump metallization layer; and then
selectively etching back the first portion of the underbump metallization layer using the solder bump as an etching mask.

2. (canceled)

3. The method of claim 2, wherein conformally depositing comprises depositing the underbump metallization layer directly onto a sidewall of the opening in the passivation layer.

4.-6. (canceled)

7. The method of claim 1, wherein the diffusion barrier layer comprises cobalt.

8. (canceled)

9. The method of claim 7, wherein the diffusion barrier layer further comprises tungsten.

10. The method of claim 9, wherein the diffusion barrier layer comprises a material selected from a group consisting of CoWP, CoWPB and CoWB.

11.-12. (canceled)

13. The method of claim 1, wherein the underbump metallization layer comprises a composite of a titanium-based diffusion barrier layer and a gold and/or platinum metal layer on the titanium-based diffusion barrier layer.

14. The method of claim 1, wherein the passivation layer comprises:
a SiCN capping layer;
a silicon dioxide insulating layer on the SiCN capping layer; and
a silicon nitride insulating layer on the silicon dioxide insulating layer.

15.-17. (canceled)

18. The method of claim 1, wherein forming a copper pattern comprises forming a two-dimensional array of copper patterns on the semiconductor substrate.

19. The method of claim 18, wherein electroless plating the diffusion barrier layer comprises electroless plating an array of spaced-apart diffusion barrier layers comprising cobalt, onto the two dimensional array of copper patterns.

20. The method of claim 19, wherein the array of spaced-apart diffusion barrier layers comprise a material selected from a group consisting of CoWP, CoWPB and CoWB.
